(19) United States
(12) Patent Application Publication
(10) Pub. No.: US 2026/0063689 A1
(43) Pub. Date: Mar. 5, 2026

(54) SYSTEMS AND METHODS FOR STORING DATA ASSOCIATED WITH AN EXCURSION EVENT DETECTED BY A POWER MONITOR DEVICE

(71) Applicant: Microchip Technology Incorporated, Chandler, AZ (US)

(72) Inventors: Tony Andresen, Chandler, AZ (US); Mitch Polonsky, Chandler, AZ (US); Daniel Meacham, Del Mar, CA (US); Todd Wimer, Gilbert, AZ (US)

(73) Assignee: Microchip Technology Incorporated, Chandler, AZ (US)

(21) Appl. No.: 19/015,194

(22) Filed: Jan. 9, 2025

Related U.S. Application Data
(60) Provisional application No. 63/689,606, filed on Aug. 30, 2024.

(51) Int. Cl. G01R 21/133

(52) U.S. Cl. CPC G01R 21/133

(57) ABSTRACT

A power monitor device includes a channel monitoring interface for monitoring a power rail, a data storage device including a data buffer, and measurement circuitry connected to the channel monitoring interface to generate a series of channel measurement samples associated with the power rail. The power monitor device includes control circuitry to store the channel measurement samples in the data buffer, detect a defined excursion event at an event detection time based at least on an event triggering sample of the channel measurement samples, and in response, store a sample set including the event triggering sample and at least one channel measurement sample stored in the data buffer prior to the event triggering sample. The control circuitry may subsequently receive a request for the stored sample set, and provide access to the stored sample set.

### RELATED APPLICATION

This application claims priority to commonly owned U.S. Provisional Patent Application No. 63/689,606 filed Aug. 30, 2024, the entire contents of which are hereby incorporated by reference for all purposes.

### TECHNICAL FIELD

The present disclosure relates to methods and apparatuses for storing measurement data associated with an excursion event (e.g., a voltage or current limit excursion) detected by a power monitor device.

### BACKGROUND

In a typical power monitoring system, e.g., for monitoring voltage and/or current of one or more power rails, when a voltage limit excursion, current limit excursion, or other excursion event is identified, the power monitoring system may output a limit excursion signal and/or the violating measurement (e.g., voltage or current) to an external user-accessible device, e.g., controller. However, measurement data before and/or after the detected limit excursion that may be relevant to diagnosing and/or addressing the cause of the limit excursion is typically not stored or otherwise available.

There is a need for improved availability of measurement data taken before and/or after a detected excursion event in a power monitoring system, e.g., to facilitate diagnosing and/or addressing the cause of the limit excursion.

### SUMMARY

The present disclosure provides systems and methods for storing (and making available to a user) measurement data taken before and/or after a detected event in a power monitoring system. A detected event may include, for example, a limit excursion (e.g., over/under voltage or current), a defined increase or decrease in voltage or current, or any other defined excursion event based on measurement data. A power monitoring system is also referred to as a power monitor, power sensor, or simply sensor. The ability to store event-related data at the power sensor may allow a user to understand what happened in the system before and after the event without interrupting the operation of the relevant controller. The ability of the sensor to store data before and/or after a detected event (e.g., limit excursion) may decrease the complexity of software and collection of multiple channels of data, e.g., associated with multiple monitored rails.

The data storage at the sensor before and/or after a detected event may be similar or analogous to the functioning of an oscilloscope, wherein a moving window of data is available for review.

In some examples, a power monitor sensor itself can store measurement data before and/or after a detected excursion event and wait for a host (e.g., controller) to request the data as needed. Operational parameters, for example (a) triggering event parameters (e.g., threshold values for over-voltage, under-voltage, over-current, under-current, etc.), and/or (b) the amount of data (e.g., number of voltage or current measurements) to be stored before and/or after a triggering event (e.g., limit excursion) can be set by a user via the controller and stored in registers or other memory of the sensor.

In some examples, the sensor may store measurement data, e.g., in SRAM memory, after ADC conversion of each measurement, according to operational parameters set by the user (or default system parameters).

In some examples, the sensor may store data across multiple channels (e.g., associated with multiple monitored rails) in response to an event detected on a particular channel, for example to allow comparison of transient behavior at different channels during an event. In some examples, storage may also be synchronized across multiple chips, for example wherein the sensor notifies another device (e.g., sensor) of an event detection, which causes the other device to store data before and/or after the event.

One aspect provides a device, e.g., a power monitor device, including a first channel monitoring interface for connection to a first power rail to define a first monitoring channel to monitor the first power rail, a first data storage device including a first data buffer, and measurement circuitry connected to the first channel monitoring interface to generate a series of first channel measurement samples associated with the first power rail. The power monitor device includes control circuitry to store the first channel measurement samples in the first data buffer, detect a defined excursion event, at an event detection time, based at least on an event triggering sample of the first channel measurement samples, and in response to detecting the defined excursion event, store a first sample set including the event triggering sample and at least one first channel measurement sample stored in the first data buffer prior to the event triggering sample. The control circuitry includes circuitry to receive a request for the stored first sample set, and in response to the received request, provide access to the stored first sample set.

In some examples, the measurement circuitry to generate the series of digital first channel measurement samples comprises an analog-to-digital converter (ADC).

In some examples, the control circuitry includes circuitry to, prior to the detection of the defined excursion event, define a size of the first sample set based on received first sample set input.

In some examples, the first sample set includes (a) the event triggering sample, (b) the at least one first channel measurement samples stored in the first data buffer prior to the event triggering sample, and (c) at least one of the first channel measurement samples generated and stored in the first data buffer after the event detection time.

In some examples, the control circuitry includes circuitry to, prior to the detection of the defined excursion event (a) receive first sample set input specifying (a) a predefined number of the at least one first channel measurement samples stored in the first data buffer prior to the event triggering sample and (b) a predefined number of the at least one of the first channel measurement samples generated and stored in the first data buffer after the event detection time, and (b) define the first sample set based on the received first sample set input.

In some examples, the control circuitry to control the measurement circuitry to continue to generate at least one first channel measurement sample after the detection of the defined excursion event, and the first sample set includes the at least one first channel measurement sample generated after the detection of the defined excursion event.

In some examples, the control circuitry includes circuitry to generate an interrupt in response to the detection of the defined excursion event, the control circuitry to control the measurement circuitry to continue to generate at least one first channel measurement sample after generating the interrupt, and the first sample set includes the at least one first channel measurement sample after the generation of the interrupt.

In some examples, the device includes a second channel monitoring interface for connection to a second power rail to define a second monitoring channel to monitor the second power rail, the measurement circuitry includes circuitry to generate a series of second channel measurement samples associated with the second power rail, and the control circuitry includes circuitry to store the second channel measurement samples in a second data buffer, in response to the detection of the defined excursion event, store a second sample set including at least one second channel measurement sample stored in the second data buffer prior to the detection of the defined excursion event, receive a request for the stored second sample set, and in response to the received request, provide access to the stored second sample set.

In some examples, the control circuitry includes circuitry to, in response to the detection of the defined excursion event, send a notification to a further power monitor device to cause the further power monitor device to store respective measurement sample data generated by the further power monitor device.

One aspect provides a method, including generating, by measurement circuitry connected to a first channel monitoring interface, a series of first channel measurement samples associated with a first power rail; storing the first channel measurement samples in a first data buffer; detecting, by control circuitry, a defined excursion event at an event detection time based at least on an event triggering sample of the first channel measurement samples; in response to the detection of the defined excursion event, storing a first sample set including the event triggering sample and at least one first channel measurement sample stored in the first data buffer prior to the event triggering sample; receiving a request for the stored first sample set; and in response to the received request, providing access to the stored first sample set.

In some examples, generating the series of first measurement samples comprises converting analog signals to digital samples by an analog-to-digital converter (ADC).

In some examples, the method includes, prior to detecting the defined excursion event, defining a size of the first sample set based on received first sample set input.

In some examples, storing a first sample set comprises storing a first sample set including (a) the event triggering sample, (b) the at least one first channel measurement samples stored in the first data buffer prior to the event triggering sample and (b) at least one of the first channel measurement samples generated and stored in the first data buffer after the event detection time.

In some examples, the method includes, prior to detecting the defined excursion event (a) receiving first sample set input specifying (i) a predefined number of the at least one first channel measurement samples stored in the first data buffer prior to the event triggering sample and (ii) a predefined number of the at least one of the first channel measurement samples generated and stored in the first data buffer after the event detection time, and (b) defining the first sample set based on the received first sample set input.

In some examples, the method includes after detecting the defined excursion event, continuing to generate at least one first channel measurement sample after the detection of the defined excursion event, wherein the first sample set includes the at least one first channel measurement sample after the detection of the defined excursion event.

In some examples, the method includes generating an interrupt in response to detecting the defined excursion event, and continuing to generate at least one first channel measurement sample after generating the interrupt, wherein the first sample set includes the at least one first channel measurement sample after generating the interrupt.

In some examples, the method includes generating, by measurement circuitry connected to a second channel monitoring interface, a series of second channel measurement samples associated with a second power rail; storing the second channel measurement samples in a second data buffer; in response to the detection of the defined excursion event by the control circuitry, storing a second sample set including at least one second channel measurement sample stored in the second data buffer prior to the detection of the defined excursion event; receiving a request for the stored second sample set; and in response to the received request, providing access to the stored second sample set.

In some examples, the method includes sending a notification to a further power monitor device in response to detecting the defined excursion event, the notification causing the further power monitor device to store respective measurement sample data generated by the further power monitor device.

One aspect provides a system, including multiple data buffers associated with multiple channels of a power monitor device, each of the multiple data buffers configured to receive a respective series of digital measurement samples associated with a respective channel of the multiple channels. The system includes control circuitry to detect a defined excursion event, at an event detection time, based at least on an event triggering sample in the series of digital measurement samples associated with a respective channel of the multiple channels; in response to detecting the defined excursion event, store a respective predefined sample set associated with each channel of the multiple channels, wherein the respective predefined sample set associated with each respective channel includes at least one of the measurement samples stored in the respective data buffer associated with the respective channel prior to the event detection time; receive a request for at least one predefined sample set associated with at least one channel of the multiple channels; and in response to the received request, provide access to the requested at least one predefined sample set.

### BRIEF DESCRIPTION OF THE DRAWINGS

Example aspects of the present disclosure are described below in conjunction with the figures, in which:

FIG. 1 shows an example power monitor device for monitoring a power rail and storing a sample set in response to detecting an excursion event;

FIG. 2 shows an example power monitor device for monitoring multiple power rails and storing respective sample sets associated with respective power rails in response to detecting an excursion event;

FIG. 3 is a flowchart of an example method of monitoring at least one power rail for an excursion event, and storing pre-event and/or post-event measurement data; and

FIG. 4 shows an example system including an example power monitor device for monitoring four power rails via four monitoring channels.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

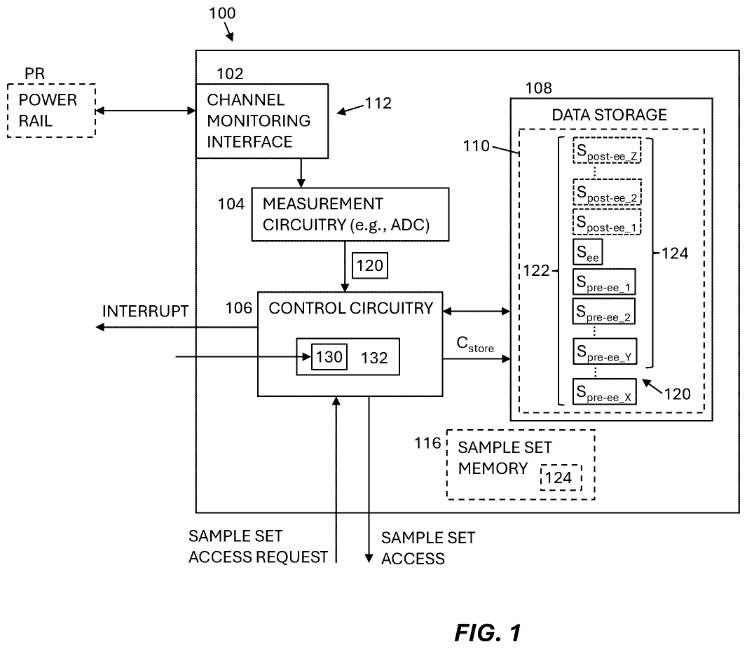

FIG. 1 shows an example power monitor device 100 for monitoring a power rail PR.

The example power monitor device 100 may include a channel monitoring interface 102, measurement circuitry 104, control circuitry 106, and a data storage device 108 including a data buffer 110. The channel monitoring interface 102 may be configured for connection to the power rail PR to define a monitoring channel 112 to monitor the power rail PR. As used herein, a power rail refers to a voltage source (e.g., a battery, DAC, capacitor, generator, or other source of AC or DC voltage) providing power to an electrical load (e.g., a fan, processor, controller, ADC, or any other circuitry or electrical load).

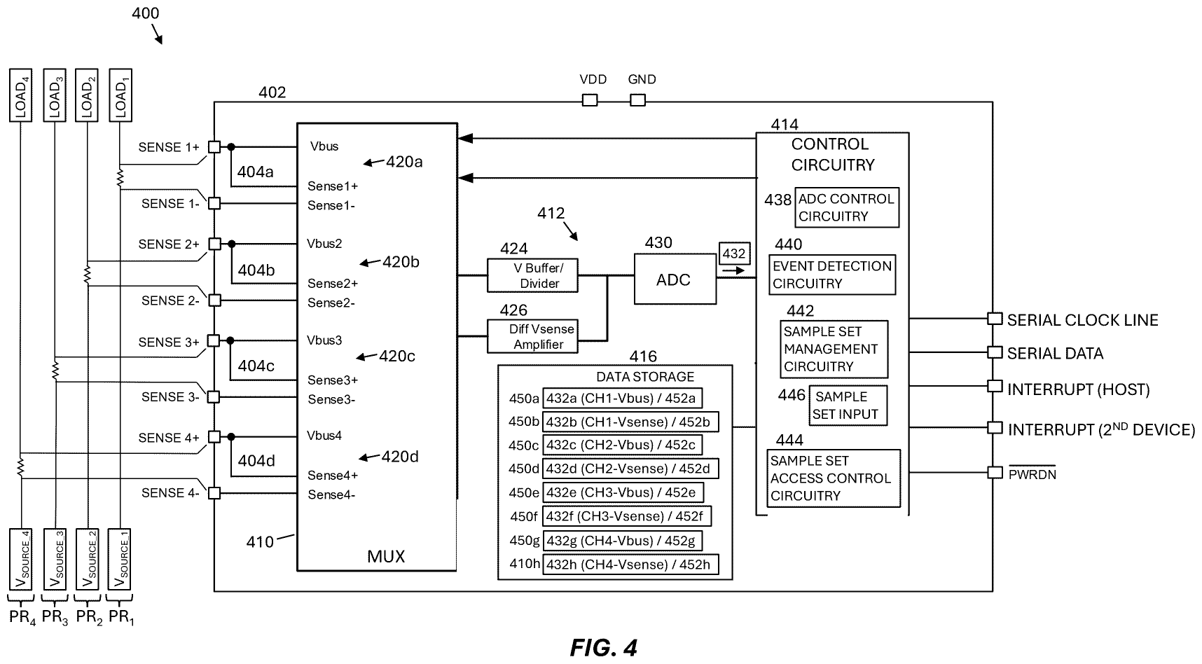

In some examples (e.g., as shown in FIG. 4 discussed below), the power rail PR comprises a voltage source, a load, and a sense resistor connected between the voltage source and load, and the channel monitoring interface 102 comprises a pair of pins or other contacts connected to measure a voltage drop across the sense resistor.

The measurement circuitry 104 is connected to the channel monitoring interface 102 and includes circuitry to generate a series of digital measurement samples 120 associated with the power rail PR. In some examples, the measurement circuitry 104 may include an analog-to-digital converter (ADC) to convert an analog voltage sensed at the channel monitoring interface 102 to a series of digital voltage values, e.g., sampled at a defined sampling frequency. The digital measurement samples 120 (e.g., digital voltage values output by an ADC) may be communicated to control circuitry 106 for analysis and to the data buffer 110 for (at least temporary) storage. Digital measurement samples 120 are also referred to herein as samples 120 for convenience.

Data storage device 108 may comprise any one or more memory device for storing samples 120, for example, one or more RAM (random access memory), ROM (read only memory), Electrically Erasable Programmable Read-Only Memory (EEPROM), or Flash memory device. In some examples, data storage device 108 may comprise a SRAM (static RAM memory) including a portion designated for the data buffer 110. The data buffer 110 may be a fixed-sized FIFO (first-in, first-out) buffer, for example a circular buffer, circular queue, cyclic buffer or ring buffer. Thus, each new digital measurement sample 120 received in the data buffer 110 may replace the oldest digital measurement sample 120 currently stored in the data buffer 110. Samples 120 stored in the data buffer 110 at any point in time may be referred to as buffered samples 122.

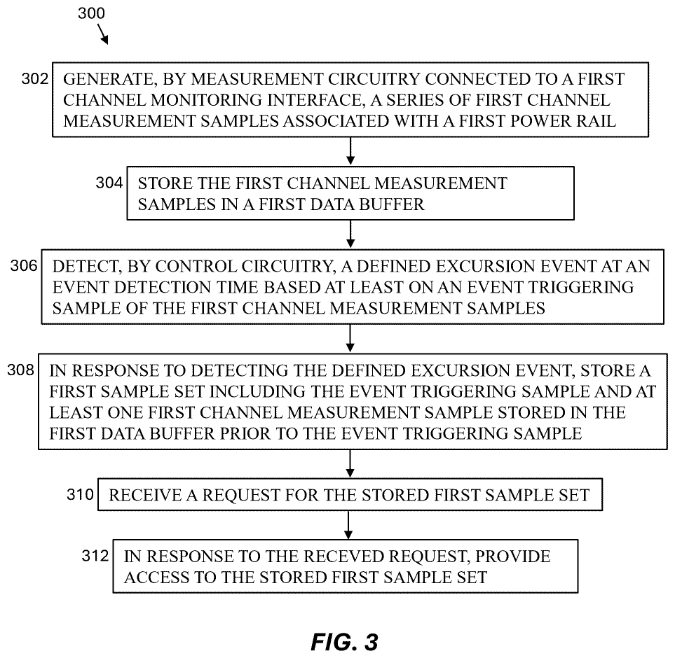

In some examples, e.g., as shown in FIG. 3 discussed below, multiple different signals associated with the power rail PR (e.g., a V_{bus} signal and a Vsense signal) may be measured via the monitoring channel 112, wherein respective samples output by the measurement circuitry 104 may be stored in respective data buffers in the data storage device 108 (or in separate data storage devices), for example, a V_{bus} data buffer and a Vsense data buffer in the data storage device 108.

The control circuitry 106 may include circuitry to detect a defined excursion event at an event detection time based on one or more digital measurement samples 120, and in response, store a sample set 124 for access by at least one external device. The respective sample 120 that triggers the detection of the excursion event detection, either by itself or in combination with one or more prior samples 120, may be referred to herein as an event triggering sample.

In response to detecting the defined excursion event, the control circuitry 106 may store a sample set 124 in the data buffer 110, in another designated area of the data storage device 108, or in an optional sample set memory 116 separate from the data storage device 108, depending on the relevant implementation, and provide access to the stored sample set 124 to at least one external device. The stored sample set 124 may include (a) event triggering sample, (b) at least a subset of buffered samples 122 present in the data buffer 110 at the event detection time, referred to herein as pre-event samples, and optionally (c) one or more samples 120 generated after the event detection time, referred to herein as post-event samples, as discussed below.

The control circuitry 106 may include circuitry to provide access to the sample set 124 (e.g., stored in data storage device 108 or the optional sample set memory 116), for example in response to receiving a request for the stored sample set 124 from an external device.

In some examples, control circuitry 106 may comprise at least one processor and logic instructions embodied as software and/or firmware stored in one or more memory device and executable by the at least one processor to perform the various functions of control circuitry 106 disclosed herein.

In some examples, during regular operation of the power monitor device 100, the control circuitry 106 may receive respective samples 120 from measurement circuitry 104 (e.g., as output from an ADC), analyze the respective samples 120 (e.g., to detect a defined excursion event), and store the respective samples 120 in the data buffer 110, e.g., before, in parallel with, or after analyzing the respective samples 120. In some examples, the control circuitry 106 may access buffered samples 122 from the data buffer 110, e.g., to analyze multiple samples 120 collectively to detect a defined excursion event.

An “excursion event” may include, for example, an out-of-limit condition defined by one or more upper and/or lower thresholds (limits) for a measured parameter (e.g., voltage) represented by the digital measurement samples 120. For example, control circuitry 106 may detect a defined excursion event by (a) detecting an overvoltage event, e.g., by detecting respective digital measurement sample(s) 120 that exceed a defined upper threshold value, (b) detecting an undervoltage event, e.g., by detecting respective digital measurement sample(s) 120 that fall below a defined lower threshold value, or (c) detecting a voltage variance event, e.g., by detecting digital measurement sample(s) 120 that indicate a variation (change) in voltage that exceeds a defined variation threshold, or a defined rate of change threshold. A respective excursion event may be detected based on a single digital measurement sample 120 (e.g., a single out-of-limit sample 120), or based on multiple digital measurement samples 120 (e.g., a defined number of consecutive out-of-limit samples 120 or a group of out-of-limit samples 120 generated within a defined time period), depending on relevant excursion event conditions implemented by the control circuitry 106.

As noted above, in response to detecting a defined excursion event, the control circuitry 106 may store a sample set 124 of samples 120 (e.g., in the data buffer 110, in another designated area of the data storage device 108, or in an optional sample set memory 116), e.g., using a store command Cₛₜₒᵣₑ, and provide access to the stored sample set 124 to external device(s), e.g., to analyze the cause or other aspects of the detected excursion event.

In some examples, in response to detection of the excursion event, the control circuitry 106 may generate an interrupt, e.g., to interrupt power delivery on the power rail PR, and instruct the measurement circuitry 104 to halt further generation of samples 120. In such examples, the stored sample set 124 may include (a) the event triggering sample 120, indicated in FIG. 1 as sample See and (b) at least one pre-event buffered sample 122 (i.e., at least one sample 120 stored in the data buffer 110 prior to the event triggering sample Sₑₑ), indicated in FIG. 1 as samples Sₚᵣₑ₋ₑₑ₋₁, Sₚᵣₑ₋ₑₑ₋₂, etc. In some examples, the stored sample set 124 may include all pre-event samples Sₚᵣₑ₋ₑₑ₋₁, Sₚᵣₑ₋ₑₑ₋₂ . . . . S_{pre-ee_X} stored in data buffer 110, while in other examples the stored sample set 124 may include a subset of pre-event samples Sₚᵣₑ₋ₑₑ₋₁, Sₚᵣₑ₋ₑₑ₋₂ . . . . Spre-ee Y stored in data buffer 110, wherein the number Y of pre-event samples included in the stored sample set 124 may be set based on user input 130, as discussed below.

In other examples, the control circuitry 106 may continue collecting samples 120 (e.g., by controlling measurement circuitry 104 to continue generating samples 120 and transferring such samples 120 to data buffer 110) after the event detection time and/or after generating an interrupt as discussed above, e.g., for a predefined number of samples 120 or for a predefined period of time after the event detection time and/or after generating an interrupt as discussed above. Such post-event samples 120 are indicated in FIG. 1 as sample Sₚₒₛₜ₋ₑₑ₋₁, Sₚₒₛₜ₋ₑₑ₋₂ . . . . S_{post-ee-Z}. In some examples, the number Z of post-event samples to be generated and included in the stored sample set 124 may be set based on user input 130, as discussed below.

Thus, as shown in FIG. 1, the sample set 124 stored by control circuitry 106 (e.g., for subsequent access by an external devices) may include (a) the event triggering sample See, (b) a number Y of pre-event samples Sₚᵣₑ₋ₑₑ₋₁-S_{pre-ee-Y}, and optionally (c) a number Z of post-event samples Sₚₒₛₜ₋ₑₑ₋₁-S_{post-ee-Z}.

As mentioned above, in some examples, the number Y of pre-event samples 120 to be included in the stored sample set 124 and the number Z of post-event samples 120 to be generated and included in the stored sample set 124 (in implementations in which post-event samples 120 are generated) may be set based on sample set input 130, e.g., received at control circuitry 106 via any suitable user interface and stored in respective registers 132 or other data storage. In some examples, sample set input 130 may specify different values of Y (number of pre-event samples 120) and/or Z (number Z of post-event samples 120) for different types or severity of detected excursion events. For example, sample set input 130 may specify first Y and Z values for an overvoltage detection, and second Y and Z values (different than the first Y and Z values) for an undervoltage detection.

In some examples, the power monitor device 100 may be configured to monitor multiple power rails, and may accordingly include a respective channel monitoring interface for each monitored power rail to define multiple monitored channels. The measurement circuitry (e.g., ADC) may generate respective samples 120 for each monitored channel, which samples 120 may be stored in respective data buffers 110, or in designated areas of a shared data buffer 110

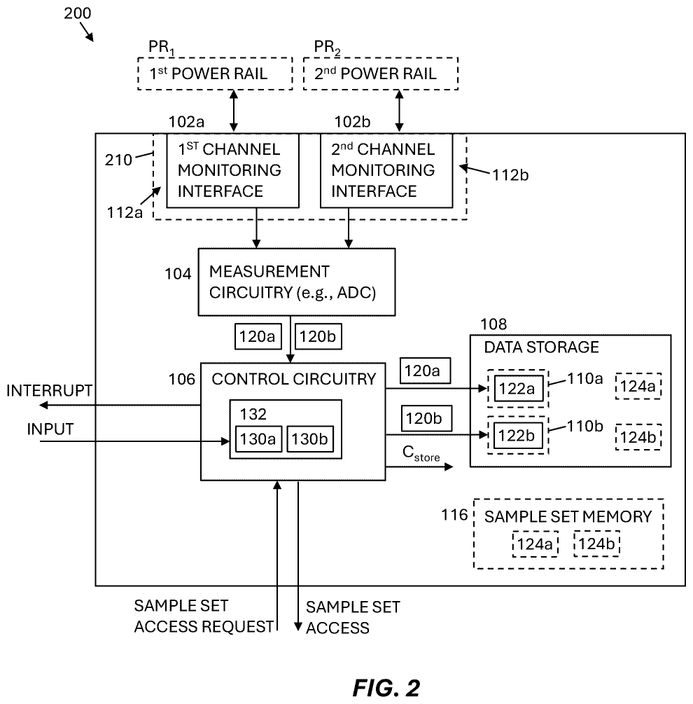

FIG. 2 shows an example power monitor device 200 for monitoring multiple power rails, for example a first power rail PR₁ including a first voltage source providing power to a first electrical load and a second power rail PR₂ including a second voltage source providing power to a second electrical load. The example power monitor device 200 may include a first channel monitoring interface 102a, a second channel monitoring interface 102b, measurement circuitry 104, control circuitry 106, and a data storage device 10 including a first data buffer 110a and a second data buffer 110b.

The first channel monitoring interface 102a is configured for connection to the first power rail PR₁ to define a first monitoring channel 112a to monitor the first power rail PR₁, and the second channel monitoring interface 102b is configured for connection to the second power rail PR₂ to define a second monitoring channel 112b to monitor the second power rail PR₂.

The measurement circuitry 104 may be connected to the first and second channel monitoring interfaces 102a, 102b to generate first and second digital measurement samples 120a and 120b (e.g., digital voltage values generated by an ADC) associated with the first and second power rails PR₁ and PR₂, respectively, and output the first and second digital measurement samples 120a and 120b. The digital measurement samples 120a and 120b may be communicated to control circuitry 106 for analysis and to the data buffers 110a and 110b, respectively, for (at least temporary) storage. Digital measurement samples 120a and 120b are also referred to herein as samples 120a and 120b for convenience.

In some examples, the measurement circuitry 104 may include an ADC to convert analog voltages sensed at first and second channel monitoring interfaces 102a and 102b to first and second digital voltage values 120a and 120b. Measurement circuitry 104 may process (e.g., ADC conversion) signals from the first and second channel monitoring interfaces 102a and 102b in an alternating manner or according to other scheduling protocol. In some examples, the first and second channel monitoring interfaces 102a and 102b are embodied in or connected to a multiplexer 210 that manages the communication of signals to measurement circuitry 104. First and second digital measurement samples 120a and 120b (e.g., digital voltage values) are also referred to herein as first samples 120a and second samples 120b, respectively, for convenience.

In some examples, each of the first data buffer 110a and second data buffer 110b may comprise a fixed-sized FIFO buffer, for example a circular buffer, circular queue, cyclic buffer or ring buffer. First samples 120a stored in the first data buffer 110a at any point in time may be referred to as first buffered samples 122a, and second samples 120b stored in the second data buffer 110b at any point in time may be referred to as second buffered samples 122b.

The control circuitry 106 may include circuitry to detect first defined excursion events on the first monitoring channel 112a (i.e., an excursion event associated with the first power rail PR₁) and/or second defined excursion events on the second monitoring channel 112b (i.e., an excursion event associated with the second power rail PR₂), wherein the first and second defined excursion events associated with the different monitoring channels 112a and 112b may be similar or different types of excursion events, e.g., using similar or different algorithms and/or threshold values for detecting respective excursion events. For example, control circuitry 106 may include (a) circuitry to detect an overvoltage condition associated with the first monitoring channel 112a by comparing a measured voltage at the first channel monitoring interface 102a with a first threshold voltage, and (b) circuitry to detect an overvoltage condition associated with the second monitoring channel 112b by comparing a measured voltage at the second channel monitoring interface 102b with a second threshold voltage different than the first threshold voltage. As another example, control circuitry 106 may include (a) circuitry to detect an overvoltage condition associated with the first monitoring channel 112a by comparing a measured voltage at the first channel monitoring interface 102a with a threshold voltage, and (b) circuitry to detect a voltage variance condition associated with the second monitoring channel 112b by comparing a variance in the measured voltage at the second channel monitoring interface 102b with a threshold variance value.

Control circuitry 106 may detect a defined excursion event associated with either the first monitoring channel 112a or the second monitoring channel 112b at an event detection time, and in response, control circuitry 106 may store both (a) a first sample set 124a associated with the first monitoring channel 112a (first power rail PR₁) and (b) a second sample set 124b associated with the second monitoring channel 112b (second power rail PR₂) in data storage device 108 or in an optional sample set memory 116.

Like the sample set 124 discussed above, the sample set corresponding with the monitoring channel on which the defined excursion event is detected may include (a) an event triggering sample, (b) one or more pre-event samples present in the respective data buffer, and in some examples (c) one or more post-event samples generated after the event detection time. The sample set corresponding with the other monitoring channel may include (a) one or more pre-event samples present in the respective data buffer, and in some examples (c) one or more post-event samples generated after the event detection time. For example, in response to detecting a defined excursion event on the first monitoring channel 112a (e.g., based on analysis of one or more first samples 120a), the control circuitry 106 may store (1) a first sample set 124a including (a) an event triggering sample 120a, (b) one or more pre-event first samples 120a present in the first data buffer 110a, and in some examples (c) one or more post-event first samples 120a generated after the event detection time, and (2) a second sample set 124b including (a) one or more pre-event second samples 120b present in the second data buffer 110b, and in some examples (c) one or more post-event second samples 120b generated after the event detection time.

In some examples, the number of pre-event samples 120a and post-event samples 120a to be included in the first sample set 124a, and the number of pre-event samples 120b and post-event samples 120b to be included in the second sample set 124b, may be set based on sample set input 130, e.g., received at control circuitry 106 via any suitable user interface and stored in respective registers 132 or other data storage.

Control circuitry 106 may allow access to the stored sample sets 124a and 124b to external device(s), e.g., which may allow a more advanced analysis of the cause or other aspects of the detected excursion event.

FIG. 3 is a flowchart of an example method 300 of monitoring at least one power rail for an excursion event, and storing pre-event and/or post-event measurement data. The method 300 may be implemented, for example by the example power monitor device 100 or 200 shown in FIG. 1 or FIG. 2, wherein the power monitor device may be configured to monitor one or more monitoring channels, each including a respective channel monitoring interface connected to a respective power rail for monitoring electrical behavior on the respective power rail.

At 302, measurement circuitry connected to a first channel monitoring interface of a first monitoring channel may generate a series of first channel measurement samples associated with a first power rail. In some examples, the measurement circuitry may also be connected to at least one additional channel monitoring interface (e.g., a second channel monitoring interface, third channel monitoring interface, etc.) to generate respective channel measurement samples associated with at least one additional power rail (e.g., a second power rail, third power rail, etc.). Generating a series of first channel measurement samples may comprise using an ADC to sample analog signals (e.g., voltage sensed at the first channel monitoring interface) to generate a series of digital values (e.g., digital voltage values). The generated first channel measurement samples may be forwarded to control circuitry for analysis and storage.

At 304, the control circuitry may store first channel measurement samples generated by the measurement circuitry in a first data buffer (e.g., a fixed-size FIFO buffer) provided in a data storage device. In examples including multiple monitoring channels, the control circuitry may store respective channel measurement samples generated for each respective monitoring channels in respective data buffers provided in the data storage device, e.g., by storing first channel measurement samples associated with a first monitoring channel in a first data buffer, second channel measurement samples associated with a second monitoring channel in a second data buffer, etc.

At 306, the control circuitry may detect a defined excursion event associated with the first power rail at an event detection time based on a current first channel measurement sample (referred to herein as an event triggering sample) and in some examples additionally one or more prior first channel measurement samples. For example, the control circuitry may detect, based on the event triggering sample (and optionally prior first channel measurement sample(s)) a voltage above or below a defend voltage threshold, which may indicate a fault condition.

At 308, in response to detecting the defined excursion event, the control circuitry stores a first sample set including (a) the event triggering sample, (b) one or more first channel measurement samples stored in the first data buffer prior to the event triggering sample (referred to herein as pre-event samples), and optionally (c) one or more first channel measurement samples generated after the event detection time, referred to herein as post-event samples. In addition, in examples including multiple monitoring channels, the control circuitry may store a respective sample set of measurement samples for each respective monitoring channel, wherein each respective sample set may include one or more pre-event samples and optionally one or more post-event samples generated and stored for the respective monitoring channel.

At 310, the control circuitry may receive a request for the stored first sample set (and/or additional sample set stored for other monitoring channels) from an external device, e.g., a host controller. In response, at 312, the control circuitry may provide access to the request stored sample set(s).

FIG. 4 shows an example system 400 including an example power monitor device 401 for monitoring four power rails PR₁-PR₄ via four monitoring channels 412a-412d. As shown, the power monitor device 402 may include four channel monitoring interfaces 404a-404d for monitoring the four power rails PR₁-PR₄, respectively. The power monitor device 401 may include a multiplexer 410, measurement circuitry 412, control circuitry 414, and a data storage device 416. In some examples, the power monitor device 401 may correspond with the example power monitor device 100 or 200 shown in FIG. 1 or FIG. 2. Accordingly, measurement circuitry 412 may correspond with measurement circuitry 104 discussed above, control circuitry 414 may correspond with control circuitry 106 discussed above, and data storage device 416 may correspond with data storage device 108 discussed above.

As shown, a first channel monitoring interface 402a may define a first monitoring channel 420a for monitoring a first power rail PR₁ including a first voltage source VSOURCE 1 providing power to a first electrical load LOAD1; a second channel monitoring interface 402b may define a second monitoring channel 420b for monitoring a second power rail PR₂ including a second voltage source VSOURCE 2 providing power to a second electrical load LOAD2; a third channel monitoring interface 402c may define a third monitoring channel 420c for monitoring a third power rail PR₃ including a third voltage source VSOURCE 3 providing power to a third electrical load LOAD3; and a fourth channel monitoring interface 402d may define a fourth monitoring channel 420d for monitoring a fourth power rail PR₄ including a fourth voltage source VSOURCE 4 providing power to a fourth electrical load LOAD4. It should be understood that although FIG. 4 shows four power rails PR₁-PR₄ monitored by four monitoring channels 420a-420d, the system 400 may similarly include any other number of power rails and corresponding monitoring channels.

In this example, each monitoring channel 420a-420d may be configured to monitor both a bus voltage Vbus and a source voltage Vsource on the respective power rail PR₁-PR₄. As shown, the four channel monitoring interfaces 402a-402d may connect to multiplexer 410 (e.g., a high voltage MUX) to manage the delivery to analog signals from the channel monitoring interfaces 402a-402d to measurement circuitry 412.

As shown, measurement circuitry 412 may include voltage dividers 424, a differential Vsense amplifier 426, and an ADC 430. Voltage dividers 424 may be provided to reduce high voltages at the SENSE input pins 420, for example voltages higher than the operational range of the ADC 430. For example, a voltage divider 424 may reduce a 30V signal at a SENSE pin 420 down to 3V (within the operational range of the ADC 430) by dividing by a factor of 10.

The ADC 430 converts analog signals from the voltage buffer/divider 424 and differential Vsense amplifier 426 to generate respective digital samples 432 for Vbus and Vsource for each monitoring channels 420a-420d, indicated as CH1-Vbus samples 432a, CH1-Vsense samples 432b, CH2-Vbus samples 432c, CH2-Vsense samples 432d, CH3-Vbus samples 432e, CH3-Vsense samples 432f, CH4-Vbus samples 432g, and CH4-Vsense samples 432h. Samples 432 output by ADC 430, including Vbus and Vsource values for each monitoring channel 420a-420d, are forwarded to control circuitry 414 for analysis and storage in data storage device 416.

As shown, control circuitry 414 may include ADC control circuitry 438, event detection circuitry 440, sample set management circuitry 442, and sample set access control circuitry 444. ADC control circuitry 438 includes circuitry to control the operation of ADC 430, including enabling and disabling the operation of ADC 430. For example, ADC control circuitry 438 may disable ADC 430 after detection of an excursion event (by event detection circuitry 440), either immediately or after a defined period or after generating a defined number of post-event samples 432.

Event detection circuitry 440 includes circuitry to detect a defined excursion event on a respective monitoring channel 420a-420d based on respective Vbus and/or Vsource samples 432 output by ADC 430. For example, event detection circuitry 440 may detect an overvoltage event, an undervoltage event, or a voltage variance event by comparing one or more Vbus and/or Vsource values with respective threshold value(s). Event detection circuitry 440 may generate interrupt(s) in response to the detected excursion event, for example a host interrupt or other interrupt to disconnect the power rail PR₁-PR₄ having the detected excursion event. In some examples, Event detection circuitry 440 may communicate an interrupt instruction to one or more connected devices (e.g., chips), along with an instruction to store sample set(s) of monitored samples associated with such connected device(s).

Control circuitry 414 may store respective Vbus and Vsource samples 432 in respective data buffers 450a-450h provided in data storage device 416. In particular, Vbus samples and Vsense samples for first monitoring channel 420a are stored in the CH1-Vbus data buffer 450a and CH1-Vsense data buffer 450b, respectively; Vbus samples and Vsense samples for second monitoring channel 420b are stored in the CH2-Vbus data buffer 450c and CH2-Vsense data buffer 450d, respectively; Vbus samples and Vsense samples for third monitoring channel 420c are stored in the CH3-Vbus data buffer 450e and CH3-Vsense data buffer 450f, respectively; and Vbus samples and Vsense samples for fourth monitoring channel 420d are stored in the CH4-Vbus data buffer 450g and CH4-Vsense data buffer 450h, respectively. In some examples, each data buffer 450a-450h may be a fixed-size FIFO buffer, e.g., having the same or different sizes. In some examples, the size of respective data buffers 450a-450h may be set or adjusted based on user input.

In some examples, control circuitry 414 may generate interrupt(s) and disable ADC 430 immediately upon detecting an excursion event. In other examples, after detecting an excursion event, control circuitry 414 may generate interrupt(s) but control ADC 430 to continue generating samples 432 of one or more of the eight different signals (CH1-Vbus samples 432a, CH1-Vsense samples 432b, CH2-Vbus samples 432c, CH2-Vsense samples 432d, CH3-Vbus samples 432e, CH3-Vsense samples 432f, CH4-Vbus samples 432g, and CH4-Vsense samples 432h) for a defined number of samples 432 or a defined time period before disabling ADC 430, e.g., as specified by sample set input 446. These post-event samples 432 may be included in respective sample sets 452a-452h stored for one or more of the eight signals.

Sample set management circuitry 442 includes circuitry to (a) define the size of respective sample sets 452a-452h for each of the eight different signals, e.g., based on sample set input 446 received from a user or otherwise, and (b) store respective sample sets 452a-452h for each of the eight different signals (or a defined subset of the eight signals, based on predefined settings) in response to detecting a defined excursion event by event detection circuitry 440.

In some examples, defining a size of each sample set 452a-452h may include defining a number of pre-event samples 432a-432h and/or a number of post-event samples 432a-432h included in the respective sample set 452a-452h, wherein the number of pre-event samples 432a-432h and/or number of post-event samples 432a-432h may be specified by sample set input 446.

Sample set access control circuitry 444 includes circuitry to allow access to sample sets 452a-452h stored after an excursion event. For example, the control circuitry 414 may receive a user request via a communication interface (e.g., an I2C interface, Serial Peripheral Interface (SPI), or other suitable interface) for access to one or more stored sample sets 452a-452h, and send the requested data to an associated host (e.g., microcontroller, embedded controller, etc.) via the serial data line (SDA) or via other communication interface.

Although example embodiments have been described above, other variations and embodiments may be made from this disclosure without departing from the spirit and scope of these embodiments.

1. A device, comprising:
a first channel monitoring interface for connection to a first power rail to define a first monitoring channel to monitor the first power rail;
a first data storage device including a first data buffer;
measurement circuitry connected to the first channel monitoring interface to generate a series of first channel measurement samples associated with the first power rail; and
control circuitry to:
store the first channel measurement samples in the first data buffer;
detect a defined excursion event, at an event detection time, based at least on an event triggering sample of the first channel measurement samples;
in response to the detection of the defined excursion event, store a first sample set including the event triggering sample and at least one first channel measurement sample stored in the first data buffer prior to the event triggering sample;
receive a request for the stored first sample set; and
in response to the received request, provide access to the stored first sample set.

2. The device of claim 1, wherein the measurement circuitry to generate the series of digital first channel measurement samples comprises an analog-to-digital converter (ADC).

3. The device of claim 1, wherein the control circuitry includes circuitry to, prior to the detection of the defined excursion event, define a size of the first sample set based on received first sample set input.

4. The device of claim 1, wherein the first sample set includes (a) the event triggering sample, (b) the at least one first channel measurement samples stored in the first data buffer prior to the event triggering sample, and (c) at least one of the first channel measurement samples generated and stored in the first data buffer after the event detection time.

5. The device of claim 4, wherein the control circuitry includes circuitry to, prior to the detection of the defined excursion event:
receive first sample set input specifying (a) a predefined number of the at least one first channel measurement samples stored in the first data buffer prior to the event triggering sample and (b) a predefined number of the at least one of the first channel measurement samples generated and stored in the first data buffer after the event detection time; and
define the first sample set based on the received first sample set input.

6. The device of claim 1, wherein:
the control circuitry to control the measurement circuitry to continue to generate at least one first channel measurement sample after the detection of the defined excursion event; and
the first sample set includes the at least one first channel measurement sample generated after the detection of the defined excursion event.

7. The device of claim 1, wherein:
the control circuitry includes circuitry to generate an interrupt in response to the detection of the defined excursion event;
the control circuitry to control the measurement circuitry to continue to generate at least one first channel measurement sample after generating the interrupt; and
the first sample set includes the at least one first channel measurement sample after the generation of the interrupt.

8. The device of claim 1, including:
a second channel monitoring interface for connection to a second power rail to define a second monitoring channel to monitor the second power rail;
the measurement circuitry includes circuitry to generate a series of second channel measurement samples associated with the second power rail; and
the control circuitry includes circuitry to:
store the second channel measurement samples in a second data buffer;
in response to the detection of the defined excursion event, store a second sample set including at least one second channel measurement sample stored in the second data buffer prior to the detection of the defined excursion event;
receive a request for the stored second sample set; and
in response to the received request, provide access to the stored second sample set.

9. The device of claim 1, wherein the control circuitry includes circuitry to, in response to the detection of the defined excursion event, send a notification to a further power monitor device to cause the further power monitor device to store respective measurement sample data generated by the further power monitor device.

10. A method, comprising:
generating, by measurement circuitry connected to a first channel monitoring interface, a series of first channel measurement samples associated with a first power rail;
storing the first channel measurement samples in a first data buffer;
detecting, by control circuitry, a defined excursion event at an event detection time based at least on an event triggering sample of the first channel measurement samples;
in response to the detection of the defined excursion event, storing a first sample set including the event triggering sample and at least one first channel measurement sample stored in the first data buffer prior to the event triggering sample;
receiving a request for the stored first sample set; and
in response to the received request, providing access to the stored first sample set.

11. The method of claim 10, wherein generating the series of first measurement samples comprises converting analog signals to digital samples by an analog-to-digital converter (ADC).

12. The method of claim 10, comprising, prior to detecting the defined excursion event, defining a size of the first sample set based on received first sample set input.

13. The method of claim 10, wherein storing a first sample set comprises storing a first sample set including (a) the event triggering sample, (b) the at least one first channel measurement samples stored in the first data buffer prior to the event triggering sample and (b) at least one of the first channel measurement samples generated and stored in the first data buffer after the event detection time.

14. The method of claim 13, comprising, prior to detecting the defined excursion event:
receiving first sample set input specifying (a) a predefined number of the at least one first channel measurement samples stored in the first data buffer prior to the event triggering sample and (b) a predefined number of the at least one of the first channel measurement samples generated and stored in the first data buffer after the event detection time; and
defining the first sample set based on the received first sample set input.

15. The method of claim 10, comprising:
after detecting the defined excursion event, continuing to generate at least one first channel measurement sample after the detection of the defined excursion event; and
wherein the first sample set includes the first sample set includes the at least one first channel measurement sample after the detection of the defined excursion event.

16. The method of claim 10, comprising:
generating an interrupt in response to detecting the defined excursion event; and
continuing to generate at least one first channel measurement sample after generating the interrupt; and
wherein the first sample set includes the at least one first channel measurement sample after generating the interrupt.

17. The method of claim 10, comprising:
generating, by measurement circuitry connected to a second channel monitoring interface, a series of second channel measurement samples associated with a second power rail;
storing the second channel measurement samples in a second data buffer;
in response to the detection of the defined excursion event by the control circuitry, storing a second sample set including at least one second channel measurement sample stored in the second data buffer prior to the detection of the defined excursion event;
receiving a request for the stored second sample set; and
in response to the received request, providing access to the stored second sample set.

18. The method of claim 10, comprising sending a notification to a further power monitor device in response to detecting the defined excursion event, the notification causing the further power monitor device to store respective measurement sample data generated by the further power monitor device.

19. A system, comprising:
multiple data buffers associated with multiple channels of a power monitor device, each of the multiple data buffers configured to receive a respective series of digital measurement samples associated with a respective channel of the multiple channels; and
control circuitry to:
detect a defined excursion event, at an event detection time, based at least on an event triggering sample in the series of digital measurement samples associated with a respective channel of the multiple channels;
in response to detecting the defined excursion event, store a respective sample set associated with each channel of the multiple channels, wherein the respective sample set associated with each respective channel includes at least one of the measurement samples stored in the respective data buffer associated with the respective channel prior to the event detection time;
receive a request for at least one sample set associated with at least one channel of the multiple channels; and
in response to the received request, provide access to the requested at least one sample set.

20. The system of claim 19, wherein the control circuitry includes circuitry to continue to generate digital measurement samples associated with a particular channel of the multiple channels after the detection of the defined excursion event; and
wherein the sample set associated with the particular channel includes the digital measurement samples generated after the detection of the defined excursion event.
